(19) United States
(12) Patent Application Publication
(10) Pub. No.: US 2005/0286625 A1
(43) Pub. Date: Dec. 29, 2005

(54) Equalizer capable of adjusting step size and equalization method thereof

(76) Inventor: Jin-hee Jung, Anyang-si (KR)

Correspondence Address: STANZIONE & KIM, LLP, 919 18TH STREET, N.W., SUITE 440, WASHINGTON, DC, 20006, US

(21) Appl. No.: 11/157,968

(22) Filed: Jun. 22, 2005

(30) Foreign Application Priority Data
Jun. 28, 2004 (KR) 2004-48940

(51) Int. Cl. H03H 7/30

(52) U.S. Cl. 375/232

(57) ABSTRACT

An equalizer capable of adjusting a step size and an equalization method. The equalizer includes an equalizer filter to remove noise from a digital symbol signal, an error determiner to determine an error of an output of the equalizer filter, a channel measurer to measure and output a channel impulse response of the digital symbol signal input into the equalizer filter, a state determiner to determine and output a reliability of the output of the equalizer filter, and a coefficient filter to receive the error, to determine a tap having a step size to be changed based on the channel impulse response, and to change the step size of the determined tap based on the reliability to update a tap coefficient of the equalizer filter.

### CROSS-REFERENCE TO RELATED APPLICATIONS

This application claims the benefit of Korean Patent Application No. 2004-48940, filed Jun. 28, 2004, in the Korean Intellectual Property Office, the disclosure of which is incorporated herein in its entirety by reference.

### BACKGROUND OF THE INVENTION

1. Field of the Invention

The present general inventive concept relates to an equalizer and an equalization method, and more particularly, to an equalizer capable of adjusting a step size at each tap by measuring a channel and feeding back a reliability of an output of the equalizer.

2. Description of the Related Art

Undesired intersymbol interference occurs in amplitude and phase of a digital communication channel due to a limited bandwidth and abnormal characteristics of the digital communication channel. Such intersymbol interference makes echo or noise as well as an original signal and is a main obstacle to efficient use of a frequency band and improvement of the performance of the frequency band. An equalizer must be used to recover a signal distorted by such intersymbol interference in a receiver receiving a digital broadcast.

An equalizer used in a receiver receiving a digital broadcast transmitted using an 8 vestigial side band (VSB) transmission method will now be described.

FIG. 1 is a block diagram of a conventional receiver 100 receiving a digital broadcast transmitted using an 8 VSB method. Referring to FIG. 1, the receiver 100 includes a tuner 101, an intermediate frequency and/or carrier recovery circuit 103, a synchronizer 105, an equalizer 107, a phase tracker 109, and a data detector 111.

A digital broadcasting signal transmitted using an 8 VSB transmission method is selected by the tuner 101 and is demodulated into a base band signal by an intermediate frequency (IF) narrow band pass filter and a frequency and phase locked loop (FPLL) of the intermediate frequency and/or carrier recovery circuit 103. The synchronizer 105 searches the demodulated signal for a sync signal in a received symbol sequence, and the equalizer 107 removes noise or echo (or ghost) generated in a wireless transmission path from the demodulated signal. The phase tracker 109 removes a residual phase error of the digital broadcasting signal having passed through the equalizer 107, the residual phase error having not been removed by the FPLL. The data detector 111, which is an apparatus performing error correction and channel decoding, performs trellis decoding, deinterleaving, Reed Solomon (RS) decoding, and derandomizing on the digital broadcasting signal.

The equalizer 107 of such a conventional receiver equalizes an input signal without information as to a state of a channel. Thus, the equalizer 107 cannot appropriately cope with variations in the states of static and dynamic channels. As a result, equalization performance is limited. Accordingly, the performance of the equalizer 107 must be improved by estimating the state of the channel to classify the static and dynamic channels and feeding back information regarding the state of the channel to the equalizer 107 to set parameters, such as a step size of the equalizer 107, appropriate for each of the static and dynamic channels.

### SUMMARY OF THE INVENTION

Accordingly, the present general inventive concept provides an equalizer capable of adjusting a step size thereof depending on an environment of a channel by measuring a state of the channel and feeding back a reliability of an output of the equalizer and an equalization method.

Additional aspects and advantages of the present general inventive concept will be set forth in part in the description which follows and, in part, will be obvious from the description, or may be learned by practice of the general inventive concept.

The foregoing and/or other aspects of the present general inventive concept are achieved by providing an equalizer capable of adjusting a step size in a receiver to receive and demodulate a modulated digital symbol signal, including an equalizer filter to remove noise from the digital symbol signal, an error determiner to determine an error of an output of the equalizer filter, a channel measurer to measure and output a channel impulse response of the digital symbol signal input into the equalizer filter, a state determiner to determine and output a reliability of the output of the equalizer filter, and a coefficient filter to receive the error, to determine a tap having a step size to change based on the channel impulse response, and to change the step size of the determined tap based on the reliability to update a tap coefficient of the equalizer filter.

The digital symbol signal may have a multiplexed data frame structure including digital image information and may be vestigial side band modulated.

The equalizer filter may include at least one tap and may separately receive a step size of each tap, and the coefficient updater may separately control step sizes of all taps of the equalizer filter.

The channel measurer may measure the channel impulse response using a method of calculating a correlation between data of the digital symbol signal and training sequence data, a method of calculating a least square, or a combination of the methods.

The state determiner may compare the output of the equalizer filter with a trellis decoded output to determine the reliability.

If the output of the equalizer filter is equal to the trellis decoded output, the state determiner may determine that the reliability is high, and if the output of the equalizer filter is different from the trellis decoded output, determine that the reliability is low.

If the reliability input from the state determiner is greater than or equal to a predetermined value, the coefficient updater may decrease the step size of the determined tap by a predetermined amount.

The equalizer filter, the error determiner, the channel measurer, the state determiner, and the coefficient updater may be integrally formed on one chip.

The channel measurer and the state determiner may be included in a central processing unit controlling the receiver.

The foregoing and/or other aspects of the present general inventive concept are also achieved by providing a receiver including an equalizer to remove noise from a vestigial side band modulated digital symbol signal having a multiplexed data frame structure, the equalizer including an equalizer filter to remove noise from the digital symbol signal, an error determiner to determine an error of an output of the equalizer filter, a channel measurer to measure and output a channel impulse response of the digital symbol signal input into the equalizer filter, a state determiner to determine and output a reliability of the output of the equalizer filter, and a coefficient filter to receive the error, to determine a tap having a step size to change based on the channel impulse response, and to change the step size of the determined tap based on the reliability to update a tap coefficient of the equalizer filter.

The foregoing and/or other aspects of the present general inventive concept are also achieved by providing an equalization method in a receiver to receive and demodulate a modulated digital symbol signal, including measuring a channel impulse response of the digital symbol signal input to an equalizer, equalizing the digital symbol signal using an equalizer to remove noise from the digital symbol signal, determining a reliability of the equalized signal, determining a tap having a step size to be adjusted based on the measured channel impulse response and adjusting the step size of the determined tap based on the reliability to separately update a tap coefficient of the equalizer.

The digital symbol signal may have a multiplexed data frame structure including digital image information and may be vestigial side band modulated.

The channel impulse response may be measured using a method of calculating a correlation between data of the digital symbol signal and training sequence data, a method of calculating a least square, or a combination of the methods.

The output of the equalizer filter may be compared with a trellis decoded output to determine the reliability.

If the output of the equalizer filter is equal to the trellis decoded output, it may be determined that the reliability is high, and if the output of the equalizer filter is different from the trellis decoded output, it may be determined that the reliability is low.

If the reliability is greater than or equal to a predetermined value, the step size may be decreased to a predetermined step

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram of a conventional receiver receiving a digital broadcast using an 8 VSB transmission method;

FIG. 2 is a block diagram illustrating an equalizer capable of adjusting a step size according to an embodiment of the present general inventive concept;

FIG. 3 is a graph illustrating an example of channel information measured by a channel measurer of the equalizer of FIG. 2;

FIGS. 4A and 4B are views illustrating an example of concerned taps selected depending on the channel information of FIG. 3;

FIG. 5 is a block diagram illustrating an equalizer capable of adjusting a step size according to another embodiment of the present general inventive concept; and

FIG. 6 is a flowchart illustrating an equalization method of adjusting a step size according to an embodiment of the present general inventive concept.

### DETAILED DESCRIPTION OF THE PREFERRED EMBODIMENTS

In the following description, same drawing reference numerals are used for the same elements even in different drawings. The matters defined in the description such as a detailed construction and elements are nothing but the ones provided to assist in a comprehensive understanding of the general inventive concept. Thus, it is apparent that the present general inventive concept can be carried out without those defined matters. Also, well-known functions or constructions are not described in detail since they would obscure the general inventive concept in unnecessary detail.

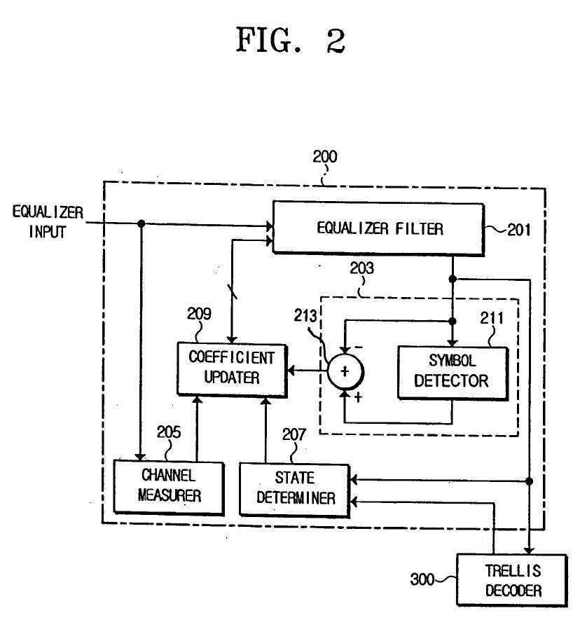

FIG. 2 is a block diagram illustrating an equalizer 200 according to an embodiment of the present general inventive concept. Referring to FIG. 2, the equalizer 200 includes an equalizer filter 201, an error determiner 203, a channel measurer 205, a state determiner 207, and a coefficient updater 209, and can be coupled to a trellis decoder 300.

The equalizer 200 can be an adaptive equalizer and can include linear and non-linear equalizers, a least mean square (LMS) equalizer, and a decision feedback (DF) equalizer. The equalizer 200 may be included in a receiver (not shown) to receive and demodulate a modulated digital symbol signal.

The equalizer 200 may be embodied as one chip. Alternatively, the equalizer filter 201, the error determiner 203, and the coefficient updater 209 may be embodied as one chip, and the channel measurer 205 and the state determiner 207 may be separately provided or may be included in a central processing unit (CPU) (not shown) controlling the receiver including the equalizer 200.

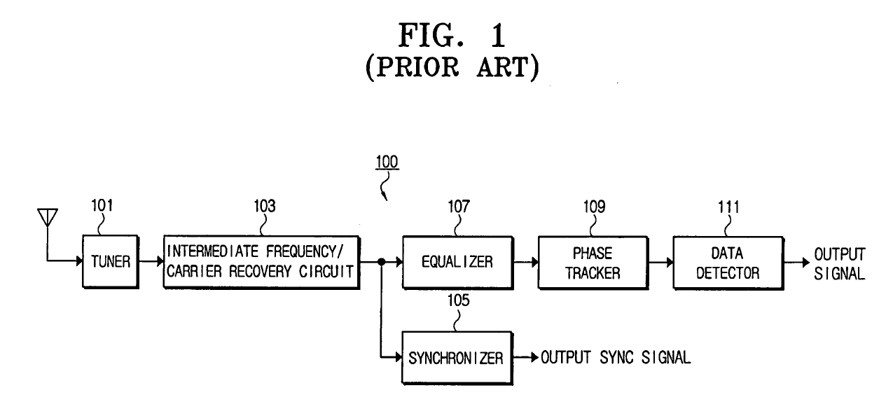

The receiver can be a digital broadcasting transceiver and can be similar to the conventional receiver 100 of FIG. 1 except for the equalizer 200. The digital symbol signal received by the receiver can have a VSB (vestigial side band) modulated and multiplexed data frame structure and can include digital image information. The following description focuses on the receiver using an 8 VSB transmission method, but the present general inventive concept is not limited thereto.

A data frame of the digital symbol signal transmitted using the 8 VSB transmission method includes two data fields, each of which includes 313 data segments. A first data segment of the 313 data segments is a field sync signal and includes a training data sequence (hereinafter referred to as a “training sequence signal”) used by the equalizer 200 of the receiver. Four symbols of each of the 313 data segments include segment syncs.

The trellis decoder 300 mainly removes white noise generated in a transmitter (not shown) and decodes an encoded signal into an original signal for error correction. The trellis decoder 300 can directly receive a signal output from the equalizer filter 201 or can receive the signal output from the equalizer filter 201 via a phase tracker (not shown), decode the signal output from the equalizer filter 201, and feed the decoded signal back to the state determiner 207.

The equalizer filter 201 can include a Feed-Forward filter and a Feedback filter. The equalizer filter 201 equalizes a signal using a plurality of taps and may apply a tap coefficient to each tap according to a predetermined coefficient update algorithm.

The error determiner 203 includes a symbol detector 211 and an adder 213. The adder 213 obtains an error value that is a difference between a signal output from the equalizer filter 201 and processed by the symbol detector 211 and the signal output from the equalizer filter 201, and outputs the error value to the coefficient updater 209.

The channel measurer 205 receives synchronized and recovered data and measures a channel impulse response (CIR) of the received data. The CIR can indicate a characteristic of a multipath channel and can include channel information, such as information regarding a position and a size of an echo. The channel measurer 205 measures the CIR using predetermined data of the received data. For example, the 8 VSB signal uses the training sequence signal of the field sync signal. The channel measurer 205 transmits the channel information to the coefficient updater 209.

The channel measurer 205 adopts a channel estimation method using the training sequence signal. The channel estimation method can include a correlation method of estimating the CIR using a correlation between the received data and the training sequence signal or a least square (LS) calculation method of calculating the CIR using the received data and the training sequence signal. The channel measurer 205 may use a combination of the correlation method and the LS calculation method.

In the correlation method, the received data is convoluted with the training sequence signal to obtain a correlation. Thus, the correlation method can be simple and estimate the CIR in a wide range. However, basic noise can be great, and thus it can be difficult to precisely estimate the CIR.

In the LS calculation method, the CIR is calculated as in Equation 1:
h=(A^{T}A)⁻¹A^{T}y (1)
Wherein h denotes N×1 channel vector, A denotes an M×N matrix including a training sequence signal, and y denotes an M×1 received data vector.

A plurality of echoes can occur in the training sequence signal of a signal received in a multipath channel environment due to a multipath on a time axis.

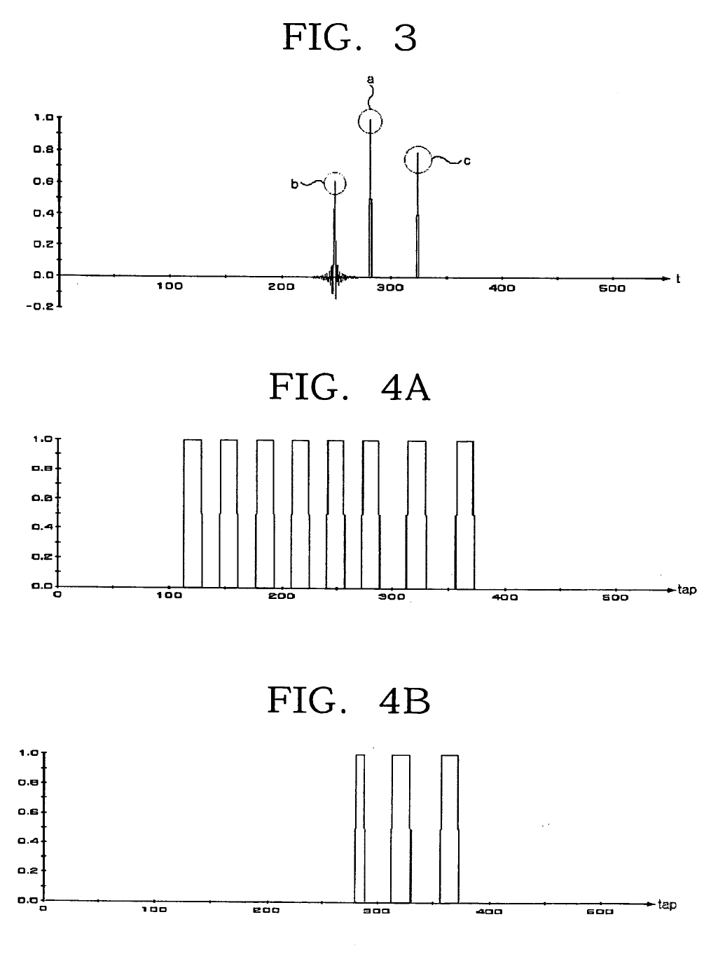

FIG. 3 is a graph illustrating an example of channel information measured by the channel measurer 205. Referring to FIG. 3, a pre-echo b and a post-echo c respectively occur before and after a main path or a main signal a on the time axis.

The state determiner 207 determines a reliability of the output of the equalizer filter 201 and outputs the reliability to the coefficient updater 209. The state determiner 207 compares the output of the equalizer filter 201 with the output of the trellis decoder 300 to determine whether the output of the equalizer filter 201 is equal to the output of the trellis decoder 300 so as to determine the reliability of the output of the equalizer filter 201.

The state determiner 207 may variously grade the reliability of the output of the equalizer 201 depending on the equality between the signals output from the equalizer filter 201 and from the trellis decoder 300. In the present embodiment, if the signal output of the equalizer filter 201 is equal to the signal output of the trellis decoder 300, the reliability of the signal output from the equalizer 201 may be output as “1.” If the signal output from the equalizer filter 201 is different from the signal output from the trellis decoder 300, the reliability of the signal output from the equalizer 201 may be output as “0.” The determined reliability is transmitted to the coefficient updater 209.

The coefficient updater 209 selects a tap (hereinafter referred to as a “concerned tap”) having a step size to be adjusted depending on the determined reliability based on the channel information measured by the channel measurer 205 and applies different step sizes to the concerned tap and any unconcerned taps. The coefficient updater 209 increases or decreases the step size of the selected concerned tap based on the reliability output from the state determiner 207. The coefficient updater 209 sets step sizes of all taps including the concerned tap and outputs the set step sizes to the equalizer filter 201.

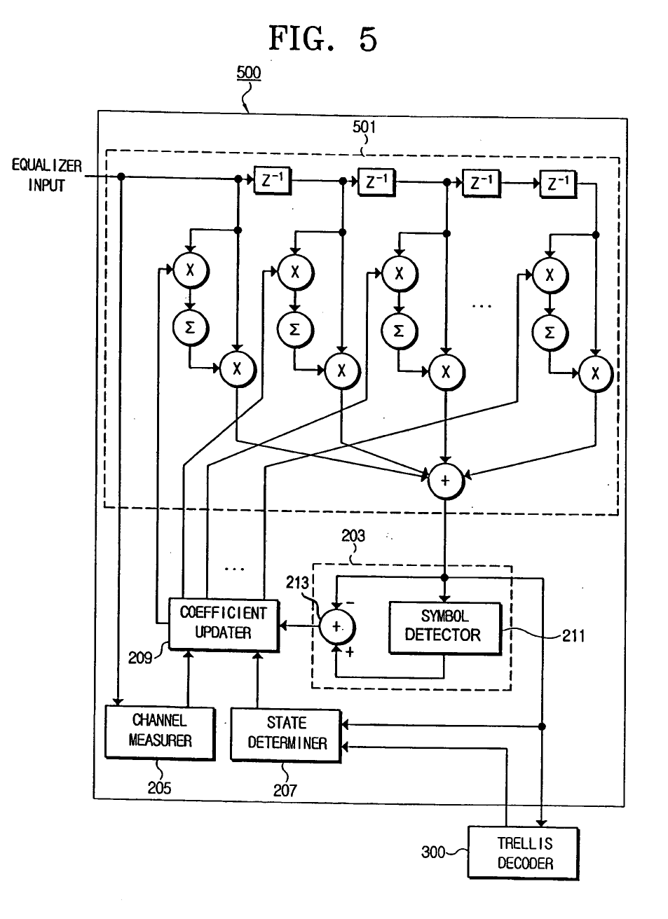

FIG. 5 is a block diagram illustrating an equalizer 500 according to another embodiment of the present general inventive concept. Some components of the equalizer 500 of FIG. 5 are similar to the corresponding components of the equalizer 200 of FIG. 2, and thus like reference numerals denote like elements. Referring to FIG. 5, an equalizer filter 501 includes a plurality of taps and applies a predetermined coefficient update algorithm to each tap. The coefficient updater 209 separately adjusts a step size of each tap.

The coefficient updater 209 can operate according to the predetermined coefficient update algorithm to update the values of the taps of the equalizer filter 201. For example, an LMS algorithm can be used as the predetermined coefficient update algorithm, and can be expressed as in Equation 2:
Cₖ₊₁=Cₖ+Δeₖrₖ (2)
wherein k denotes a number of time iterations and generally a time flow of a symbol interval, Cₖ denotes a coefficient vector of k^{th} iteration, rₖ denotes an input data vector, Δ denotes a step size, and eₖ denotes an error value. A cardinality of a vector is equal to a number of taps of the equalizer filter 201. The coefficient updater 209 controls Δeₖrₖ in Equation 2. Alternatively, a Signed LMS algorithm can be used as the predetermined coefficient update algorithm, and can be expressed as in Equation 3:
Cₖ₊₁=Cₖ±Δrₖ (3)
wherein “+” denoted a case where the error value eₖ is greater than or equal to “0,” and “−” denotes a case where the error value eₖ is less than “0.” The coefficient updater 209 controls Δrₖ in Equation 3.

The coefficient updater 209 selects a concerned tap having a step size to be specifically adjusted based on the channel information output from the channel measurer 205. The equalizer filter 501 can include a Feed-Forward filter and a Feedback filter. The coefficient updater 209 can select a first concerned tap used for the Feed-Forward filter to remove the pre-echo and a second concerned tap used for the Feedback filter to remove the post-echo.

FIGS. 4A and 4B are views illustrating examples of selecting concerned taps based on the channel information shown in FIG. 3. A bar graph illustrated in FIG. 4A denotes the first concerned tap of the Feed-Forward filter selected to remove the pre-echo, and a bar graph illustrated in FIG. 4B denotes the second concerned tap of the Feedback filter selected to remove the post-echo. The concerned taps are selected by adding an appropriate tap to a tap corresponding to echo to be removed. Referring to FIG. 4A, in addition to the first concerned tap corresponding to the pre-echo, different concerned taps selected according to the coefficient update algorithm are illustrated.

Predetermined step sizes are applied to concerned taps, and step sizes smaller than the predetermined step sizes are applied to unconcerned taps. A minimum step size may be applied to all of the unconcerned taps.

The coefficient updater 209 adjusts the step size applied to the concerned tap based on the reliability determined by the state determiner 207. If the reliability is “0,” the coefficient updater 209 increases or maintains a current step size. If the reliability is “1,” the coefficient updater 209 decreases the current step size in step increments.

If the reliability is “1,” the coefficient updater 209 can decrease the current step size until the step size reaches the minimum value. Such a process of decreasing a step size may be shown in a static channel in which a size and a position of an echo are static. However, the state of a channel may constantly vary. Thus, if the reliability is “1” and the step size is decreasing, the channel may be a dynamic channel in which the position and the size of an echo vary. When the reliability is “0” in such a channel environment, the coefficient updater 209 re-increases the step size and adapts to the variations in the channel. The result of the CIR of the channel measurer 205 is changed, and thus the coefficient updater 209 can re-select a tap based on the changed result of the CIR.

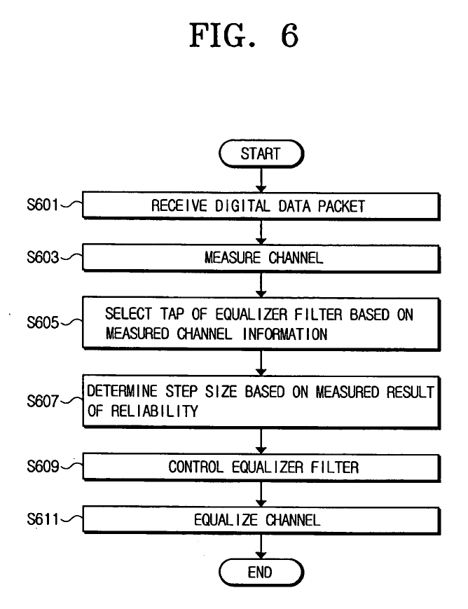

FIG. 6 is a flowchart illustrating an equalization method of adjusting a step size according to an embodiment of the present general inventive concept. Operations of an equalizer capable of adjusting a step size, such as the equalizer 200 of FIG. 2 or the equalizer 500 of FIG. 5, according to the embodiments of the present general inventive concept, will now be described with reference to FIGS. 2 and 6.

At operation S601, the channel measurer 205 receives digital data into which a digital broadcasting data packet has been synchronized and recovered. At operation S603, the channel measurer 205 measures a CIR of the digital data. The channel measurer 205 transmits the measured CIR to the coefficient updater 209.

At operation S605, the coefficient updater 209 selects a concerned tap having a step size to be adjusted based on the CIR received from the channel measurer 205. The coefficient updater 209 applies a predetermined step size to the concerned tap and a minimum step size to unconcerned taps to update a coefficient of each tap.

The state determiner 207 compares a signal output from the equalizer filter 201 with a signal output from the trellis decoder 300 to determine a reliability of the output of the equalizer filter 201. If the signal output from the equalizer filter 201 is equal to the signal output from the trellis decoder 300, the state determiner 207 outputs the reliability as “1” to the coefficient updater 209. If the signal output from the equalizer filter 201 is not equal to the signal output from the trellis decoder 300, the state determiner 207 outputs the reliability as “0” to the coefficient updater 209.

At operation S607, the coefficient updater 209 determines whether to decrease the step size depending on the reliability determined by the state determiner 207. If the reliability is “1,” the coefficient updater 209 decreases the step size. If the reliability is “0,” the coefficient updater 209 increases or maintains the step size.

At operation S609, the coefficient updater 209 adjusts each tap of the equalizer filter 201 using the selected step size. At operation S611, the coefficient updater 209 equalizes an input signal depending on variations in a channel.

The equalization method of an equalizer capable of adjusting the step size according to the embodiments of the present general inventive concept can be embodied according to the above-described process.

As described above, in an equalizer capable of adjusting a step size and an equalization method according to various embodiments of the present general inventive concept, a position of a multipath can be estimated through the estimation of a channel prior to equalization. Step sizes of filter taps corresponding to the position of the multipath and step sizes of filter taps not corresponding to the position of the multipath can be set differently. Thus, a distortion of the channel can be efficiently compensated for. As a result, compared to a conventional equalization method of equally setting step sizes of all taps, the equalization method can cope with environment changes between static and dynamic channels. Also, step sizes can be changed using reception state information of a trellis decoder to improve the performance of an equalizer.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. An equalizer capable of adjusting a step size in a receiver to receive and demodulate a modulated digital symbol signal, comprising:
an equalizer filter to remove noise from the digital symbol signal;
an error determiner to determine an error of an output of the equalizer filter;
a channel measurer to measure and output a channel impulse response of the digital symbol signal input into the equalizer filter;
a state determiner to determine and output a reliability of the output of the equalizer filter; and
a coefficient filter to receive the error, to determine a tap having a step size to change based on the channel impulse response, and to change the step size of the determined tap based on the reliability to update a tap coefficient of the equalizer filter.

2. The equalizer of claim 1, wherein the digital symbol signal has a multiplexed data frame structure comprising digital image information and is vestigial side band modulated.

3. The equalizer of claim 1, wherein:
the equalizer filter comprises at least one tap and separately receives a step size of each tap, and
the coefficient updater separately controls step sizes of all taps of the equalizer filter.

4. The equalizer of claim 1, wherein the channel measurer measures the channel impulse response using one of a method of calculating a correlation between data of the digital symbol signal and training sequence data, a method of calculating a least square, and a combination of the methods.

5. The equalizer of claim 1, wherein the state determiner compares the output of the equalizer filter with a trellis decoded output to determine the reliability.

6. The equalizer of claim 5, wherein if the output of the equalizer filter is equal to the trellis decoded output, the state determiner determines that the reliability is high, and if the output of the equalizer filter is different from the trellis decoded output, determines that the reliability is low.

7. The equalizer of claim 5, wherein if the reliability input from the state determiner is greater than or equal to a predetermined value, the coefficient updater decreases the step size of the determined tap by a predetermined amount.

8. The equalizer of claim 1, wherein the equalizer filter, the error determiner, the channel measurer, the state determiner, and the coefficient updater are integrally formed on one chip.

9. The equalizer of claim 1, wherein the channel measurer and the state determiner are provided in a central processing unit controlling the receiver.

10. The equalizer of claim 1, wherein the equalizer filter, the error determiner, and the coefficient updater are integrally formed on one chip, and the channel measurer and state determiner are included in a central processing unit controlling the receiver.

11. A receiver comprising:
an equalizer to remove noise from a vestigial side band modulated digital symbol signal having a multiplexed data frame structure, the equalizer including:
an equalizer filter to remove noise from the digital symbol signal;
an error determiner to determine an error of an output of the equalizer filter;
a channel measurer to measure and output a channel impulse response of the digital symbol signal input into the equalizer filter;
a state determiner to determine and output a reliability of the output of the equalizer filter; and
a coefficient filter to receive the error, to determine a tap having a step size to change based on the channel impulse response, and to change the step size of the determined tap based on the reliability to update a tap coefficient of the equalizer filter.

12. An equalizer, comprising:
an equalizer filter having a plurality of taps to equalize an input digital signal;
a calculating unit to measure channel information of the input digital signal and to measure a reliability of the equalized digital signal; and
a tap adjusting unit to select at least one of the plurality of taps of the equalizer filter according to the measured channel information and to adjust a step size of the at least one selected tap independently from the remaining taps according to the measured reliability.

13. The equalizer of claim 12, wherein the equalizer filter comprises:
a feed-forward filter; and
a feedback filter.

14. The equalizer of claim 13, wherein the tap adjusting unit selects a first tap to be used by the feed-forward filter to remove a pre-echo from the input digital signal and a second tap to be used by the feedback filter to remove a post-echo from the input digital signal.

15. The equalizer of claim 12, wherein the equalized digital signal is decoded by an external decoder, and the calculating unit compares the equalized digital signal with decoded equalized digital signal to measure the reliability of the equalized digital signal.

16. The equalizer of claim 15, wherein when the equalized digital signal is equal to the decoded equalized digital signal, the tap adjusting unit decreases the step size of the at least one selected tap.

17. The equalizer of claim 12, further comprising:
an error determining unit to determine an error value of the equalized digital signal, wherein the tap adjusting unit adjusts coefficients of each of the plurality of taps according to the determined error value.

18. An equalizer, comprising:
an equalization filter having one or more taps to equalize an input digital signal; and
a tap control unit to select at least one of the taps according to a channel impulse response of the input digital signal, to set a step size of the selected at least one tap to a first predetermined value and a step size of the remaining taps to a second predetermined value, and to adjust the step size of the selected at least one tap according to a reliability of the equalized digital signal.

19. The equalizer of claim 18, wherein the first predetermined value is greater than the second predetermined value.

20. The equalizer of claim 19, wherein the tap control unit incrementally decreases the step size of the selected at least one tap when the equalized digital signal is reliable.

21. The equalizer of claim 18, wherein the tap control unit comprises:
a channel measurer to measure the channel impulse response of the input digital signal; and
a state determining unit to measure the reliability of the equalized digital signal.

22. An equalizer, comprising:
an equalization filter having one or more taps to equalize an input digital signal;
a multipath identifier to identify a location of a multipath in the input digital signal; and
a tap control unit to independently control a coefficient and a step size of each tap and to set the step size of taps corresponding to the indentified position of the mutlipath to be different from the step size of taps not corresponding to the identified position of the multipath.

23. An equalization method in a receiver receiving and demodulating a modulated digital symbol signal, comprising:
measuring a channel impulse response of the digital symbol signal input to an equalizer;
equalizing the digital symbol signal to remove noise from the digital symbol signal;
determining a reliability of the equalized signal;
determining a tap having a step size to be adjusted based on the measured channel impulse response and adjusting the step size of the determined tap based on the reliability to separately update a tap coefficient of the equalizer.

24. The equalization method of claim 23, wherein the digital symbol signal has a multiplexed data frame structure comprising digital image information and is vestigial side band modulated.

25. The equalization method of claim 23, wherein the measuring of the channel impulse response comprises one of:
calculating a correlation between data of the digital symbol signal and training sequence data;
calculating a least square between data of the digital symbol signal and training sequence data; and
a combination of calculating the correlation and the least square between data of the digital symbol signal and training sequence data.

26. The equalization method of claim 23, wherein the determining of the reliability of the equalized signal comprises:
comparing the equalized signal output from the equalizer filter with a trellis decoded equalized signal.

27. The equalization method of claim 26, wherein the determining of the reliability of the equalized signal further comprises:
if the equalized signal output from the equalizer filter is equal to the trellis decoded equalized signal, determining that the reliability is high; and
if the equalized signal output from the equalizer filter is different from the trellis decoded equalized signal, determining that the reliability is low.

28. The equalization method of claim 26, wherein the adjusting of the step size of the determined tap comprises:
if the reliability is greater than or equal to a predetermined value, decreasing the step size if the determined tap by a predetermined amount.

29. An equalization method comprising:
estimating a position of a multipath in an input signal; and
equalizing the input signal by setting step sizes of filter taps corresponding to the position of the multipath and step sizes of filter taps not corresponding to the position of the multipath differently.

30. The equalization method of claim 29, further comprising:
adjusting the set step size of the filter taps corresponding to the position of the multipath based on a reliability measurement of the equalized signal.
